(19) United States
(12) Patent Application Publication
(10) Pub. No.: US 2026/0357469 A1
(43) Pub. Date: Nov. 12, 2026

(54) METHOD FOR PRODUCING A COMPOSITE COPPER FOIL AND COMPOSITE COPPER FOIL OBTAINED THEREWITH

(71) Applicant: CIRCUIT FOIL LUXEMBOURG, WILTZ (LU)

(72) Inventors: Zainhia KAIDI, Bastogne (BE); Sascha SCHOLZEN, Waimes (BE); Adrien KERSTEN, Ferrieres (BE); Michel STREEL, Houffalize (BE)

(73) Assignee: CIRCUIT FOIL LUXEMBOURG, WILTZ (LU)

(21) Appl. No.: 19/130,648

(22) PCT Filed: Nov. 29, 2023
(86) PCT No.: PCT/EP2023/083518

§ 371 Date: May 16, 2025

(30) Foreign Application Priority Data
Dec. 22, 2022 (LU) LU503243

(51) Int. Cl. C25D 7/06; C25D 3/38; C25D 5/34

(52) U.S. Cl. CPC C25D 7/0614; C25D 3/38; C25D 5/34

(57) ABSTRACT

The invention concerns a method for producing a peelable composite copper foil comprising:
providing a carrier foil;
depositing a release layer comprising a ternary alloy of nickel, molybdenum and tungsten on the carrier foil, using an acidic electrolyte comprising nickel, molybdenum and tungsten, the release layer being an amorphous layer;
washing an exposed side of release layer on the carrier foil with a washing solution having a pH comprised between 2.5 and 4.5;
electroplating an ultra-thin copper foil on the release layer.

The invention also concerned the obtained composite copper foil comprising a carrier foil, a release layer and an ultra-thin copper foil in this order, wherein the release layer comprises a ternary alloy of nickel, molybdenum and tungsten formed as amorphous layer, and wherein a peel strength of the release layer is comprised between 30 and 120 N/m after lamination at 170 C for 1 h.

### FIELD OF THE INVENTION

The present invention generally relates to the field of composite copper foils and more specifically to composite copper foils with a release layer, and to a producing method thereof.

### BACKGROUND OF THE INVENTION

With the miniaturization of electronic devices, an ultra-thin copper foil that has a thickness of about 5 μm or less has been used as an electronic material for a printed circuit board (PCB). Such an ultra-thin copper foil is generally not self-supporting, and thus is not easy to use. In order to address such an issue, a composite copper foil in which an ultra-thin copper layer is attached to a carrier (support) layer is being used.

Composite foils are generally divided into two types: i.e. foils with peelable carriers and foils with etchable carriers. Briefly, the difference between the two types of composite foils lies in the method of removing the carrier layer. In peelable composite foils, the carrier layer is removed by peeling, whereas in etchable composite foils, the carrier layer is removed by etching.

Peelable composite foils are generally preferred to etchable composite foils as they allow simpler and more precise preparation of copper clad laminates. Indeed, chemical etching of the carrier is long-due to its relatively important thickness-requires several changes of etching baths and results in a rough surface. In addition, it limits the choice in carrier layer since the ultra-thin copper layer must not be etched.

Peelable composite foils are thus much easier to use than etchable foils. However, a recurrent problem of conventional peelable composite foils is the difficulty of controlling their peel strength, i.e. the force needed to separate the carrier foil from the ultra-thin copper foil, after lamination.

A conventional composite copper foil and its production method are known from U.S. Pat. No. 3,998,601, wherein the carrier and functional foils are joined via a release layer formed using an electroplating bath comprising hexavalent chromium. However, such composite copper foils are covered by the REACH regulation and their production will no longer be possible after 2023 due to the use of hexavalent chromium.

To overcome this limitation, alternative manufacturing processes have been developed. Document WO 2020/173574 A1, for example, discloses a method to produce a peelable composite copper foil without the use of chromium. The release layer is formed as an amorphous layer of a binary or ternary nickel alloy. Such composite copper foils have a low peeling strength upon lamination typically comprised between 5 and 30 N/m, and are perfectly adapted for some markets where composite foils are submitted to a lamination process at relatively high temperature, typically around 220 °C, and the carrier layer being peeled off after this lamination step. It may be noted here that under the lamination process, the applied temperature has the effect of increasing the bonding between the carrier layer and the functional foils. That is, during lamination the temperature will increase the initially low peel strength, hence increasing the stability of the assembly and avoiding unintentional separation of the peelable foil.

By contrast, in Europe the industry typically uses processes involving lamination at lower temperatures, typically below 180 °C. Tests carried out with the composite copper foil of WO 2020/173574 A1 have shown that after low temperature lamination, the peel strength is close to zero. Hence it is impossible to ensure a satisfactory sticking of the carrier layer, which therefore cannot act as a protection during subsequent processing of the copper clad laminate. Composite copper foils as disclosed in WO 2020/173574 A1 are therefore not adapted for use in low temperature lamination processes.

### OBJECT OF THE INVENTION

It is an object of the present invention to provide a method for producing a composite copper foil with a high release strength adapted for low temperature lamination, while being compatible with the REACH regulation.

### SUMMARY OF THE INVENTION

In order to achieve the above-mentioned object, the present invention proposes a method for producing a composite copper foil comprising a carrier foil, a release layer and an ultra-thin copper foil, the ultra-thin copper foil being peelable from the carrier foil, the method comprising:
providing a carrier foil;
depositing a release layer comprising a ternary alloy of nickel, molybdenum and tungsten on one side of the carrier foil, using an acidic electrolyte comprising nickel, molybdenum and tungsten, the release layer being an amorphous layer;
washing an exposed side of release layer on the carrier foil with a washing solution having a pH comprised between 2.5 and 4.5;
   electroplating an ultra-thin copper foil on the release layer.

The present method allows production of a composite copper foil having, upon low temperature lamination, a peel strength in the range of 30 to 120 N/m, preferably between 40 and 120 N/m. As it will be understood, the peel strength may be adapted for a given application. Therefore, in embodiments the peel strength may be in the range from 40 up to 80, 90 or 100 N/m, in other embodiments the peel strength may range from 70 or 80 up to 120 N/m. Still in other embodiments the peel strength may be in the range from 70 to 90 N/m.

As used herein, the term ‘peel strength’ designates the force needed to separate the carrier foil from the ultra-thin copper foil. Since the bonding between the carrier foil from the ultra-thin copper foil is due to the release layer, the peel strength may also be referred to as ‘release strength’ in the field. In practice, peel strength is usually measured after lamination.

It will be appreciated that the present inventors have found that the washing step, applied to the exposed side of the release layer, allows controlled oxidation of the surface of the release layer and thereby allows to control the peel strength of the composite copper foil. The bulk of the release layer is not affected by the washing step, only the surface. Since the ultrathin copper foil is formed on the washed side of the release layer, oxides of the components/elements of the ternary alloy exist at the interface with the ultrathin copper foil, which influences/controls the peel strength.

Compared to the composite copper foil of WO 2020/173574 A1, the present inventors have surprisingly found that the washing step permits increasing the peel strength to higher ranges, while the carrier foil remains peelable at a lamination step at a temperature of up to 170 °C.

In other words, the invention is based on the findings by the present inventors that a specific method step comprising the washing of a release layer with an acidic washing solution, allows manufacturing a composite copper foil suitable for lamination at low temperature, presenting a peel strength-after lamination at 170 °C for 1 hour—that is comprised between 30 and 120 N/m.

The present invention relies on the use of a washing solution to wash the release layer in order to control the peel strength of the composite copper foil. Indeed, the inventors found out that washing the release layer with a washing solution induces the formation of oxides at the surface of the release layer. The presence and amount of oxide adjust (i.e. control) the peel strength of the composite copper foil. The peel strength, i.e. the bonding force between the carrier and the ultra-thin copper foil, may thus be controlled by a fine tuning of the washing step, thereby controlling the formation of oxides.

Moreover, as the release layer is formed as an amorphous alloy layer, it presents a smooth surface with substantially no irregularities due to grain boundaries, thereby preventing the formation of structural defects, such as e.g. pinholes, in a foil deposited thereon. In other words, the formation of the release layer as an amorphous layer allows manufacturing a composite copper foil which is free of structural defects such as e.g. pinholes.

In embodiments, a pH of the washing solution is comprised between 2.5 and 4.0, preferably between 2.5 and 3.5. According to the same or different embodiments, the washing solution comprises water and any appropriate acid, preferably an inorganic acid, such as e.g. H₂SO₄, HCl, etc.

In preferred embodiments, washing the exposed side of the release layer (i.e. the washing step) comprises spraying the washing solution onto the exposed side of the release layer and/or dipping the carrier foil with the release layer deposited thereon in the washing solution. More preferably, the washing step comprises, in this order, spraying the washing solution onto the exposed surface of the release layer, dipping the carrier foil with the release layer in the washing solution, and once again spraying the washing solution onto the exposed side of the release layer.

In embodiments, washing the exposed side of the release layer (i.e. the washing step) is performed during a time period comprised between 10 and 50 s, preferably between 10 and 30 s. In embodiments wherein the washing step comprises both spraying with and dipping in the washing solution, the dipping is preferably performed with a time corresponding to 20 to 25% of the total time of the washing step.

In embodiments, the washed release layer may be wiped by passing through rotating rollers, e.g. nip rollers.

According to the same or other embodiments, the washed released layer may be left in air for 10 to 40 s to dry the washed release layer.

According to the same or other embodiments, the acidic electrolyte comprises nickel at a concentration between 5.0 and 9.0 g/L, preferably between 7.0 and 9.0 g/L, more preferably between 7.5 and 8.5 g/L, molybdenum at a concentration between 5.0 and 9.0 g/L, preferably between 5.0 and 7.0 g/L, more preferably between 5.5 and 6.5 g/L and tungsten at a concentration between 1.0 and 5.0 g/L, preferably between 2.0 and 4.0 g/L, more preferably between 2.5 and 3.5 g/L.

The inventors surprisingly found out that electrodepositing the release layer from an electrolytic bath with such prescribed composition is particularly efficient in combination with the washing step to achieve the desired peel strength upon lamination at low temperature.

In embodiments, electroplating the ultra-thin copper foil comprises:
electroplating directly on the release layer a first copper layer using an alkaline copper electrolyte; and
electroplating a second copper layer on the first copper layer using an acidic copper electrolyte.

Preferably, the alkaline bath may comprise pyrophosphate, cyanate and/or sulfamate ions.

According to another aspect, the present invention relates to a composite copper foil comprising a carrier foil, a release layer and an ultra-thin copper foil in this order, wherein the composite copper foil has a peel strength comprised between 30 and 120 N/m after lamination at 170 °C for 1 h.

In embodiments the peel strength may be in the range from 40 up to 80, 90 or 100 N/m, in other embodiments the peel strength may range from 70 or 80 up to 120 N/m. Still in other embodiments the peel strength may be in the range from 70 to 90 N/m.

The release layer comprises an amorphous ternary alloy of nickel, molybdenum and tungsten.

In embodiments, the release layer includes oxide forms of nickel, wherein nickel with an oxidation state of +II represents at least 30% by weight, of the total amount of the nickel at the surface. In embodiments, the amount of Ni (+II) may be between 30 and 50% by weight of the total amount of the nickel at the surface. First test show that such proportion of forms of Ni in oxidized form permit to produce copper foils with the desired peel strength property.

As mentioned above with respect to the inventive method, the present invention is based on the findings by the inventor that the presence of oxides of the components/elements of the ternary alloy, in particular oxide forms of nickel, at the interface with the ultra-thin copper foil influences/controls the peel strength of the composite copper foil.

The presence and amount of oxide forms of nickel (i.e. nickel oxides) adjust (i.e. control) the peel strength of the composite copper foil. The peel strength, i.e. the bonding force between the carrier and the ultra-thin copper foil, may thus be controlled by a fine tuning of the amount of nickel oxides.

Moreover, as the release layer comprises an amorphous alloy layer, it presents a smooth surface with substantially no irregularities due to grain boundaries, thereby preventing the formation of structural defects, such as e.g. pinholes, in a foil deposited thereon. In other words, the release layer comprising an amorphous layer allows the composite copper foil to be free of structural defects such as e.g. pinholes.

Any other advantage recited with respect to the inventive method applies mutatis mutandis to the inventive composite copper foil.

According to the same or other embodiments, the release layer has a thickness between 5 and 50 nm, preferably between 30 and 50 nm, more preferably between 35 and 50 nm.

Advantageously, a thickness of the ultra-thin copper foil is may be comprised between 0.5 and 10 μm, in particular between 5 and 9 μm, depending on the intended application of the composite copper foil.

According to yet another aspect, the present invention relates to a copper clad laminate comprising a substrate with a resin, and a composite copper foil as disclosed, the ultra-thin copper foil being laminated onto an exposed surface of the substrate,
wherein the resin of the substrate has a Tg lower than 170 °C, and
wherein, after lamination at 170 °C for 1 h, the peel strength of the release layer is comprised between 30 and 120 N/m after lamination at 170 °C for 1 h.

Advantageously, the composite copper foil is produced using a method according to the invention, or the composite copper foil is a composite copper foil according to the invention.

What was said regarding advantages and embodiments of the inventive composite copper foil applies mutatis mutandis to the inventive copper clad laminate.

As used herein, the term ‘amorphous’ refers to a case where a broad diffraction peak appears when measured by Grazing Incidence X-ray Diffraction (GIXRD) or where a hollow pattern appears at peaks when electron beam diffraction is measured by using a Transmission Electron Microscope (TEM).

In the present context, any given numeric value covers a range of values form −10% to +10% of said numeric value, preferably a range of values form −5% to +5% of said numeric value, more preferably a range of values form −1% to +1% of said numeric value.

Further details and advantages of the present invention will be apparent from the following detailed description of several not limiting embodiments with reference to the attached drawings.

### BRIEF DESCRIPTION OF THE DRAWINGS

The present invention will now be described, by way of example, with reference to the accompanying drawings, in which:

FIG. 1 is a cross-sectional view illustrating a composite copper foil according to an embodiment of the present invention.

FIG. 2 is a cross-sectional view illustrating the functional foil of FIG. 1.

FIG. 3 are graphs of intensity (arbitrary units-CPS) versus binding energy (electronvolts (eV)) showing the results of X-ray photoelectron spectroscopy (XPS) analysis in the Ni region of the surface of the release layer of two composite copper foils produced according to the invention.

FIG. 4 are graphs of intensity (arbitrary units-CPS) versus binding energy (electronvolts (eV)) showing the results of X-ray photoelectron spectroscopy (XPS) analysis in the Ni region of the surface of the release layer of two comparative composite copper foils.

FIG. 5 is a principle diagram of a production line for implementing the present method.

### DETAILED DESCRIPTION OF PREFERRED EMBODIMENTS

Embodiments of the present method and of the composite copper foil that is obtained with the present method will now be described. For ease of explanation, the composite copper foil is presented first.

### The Composite Copper Foil

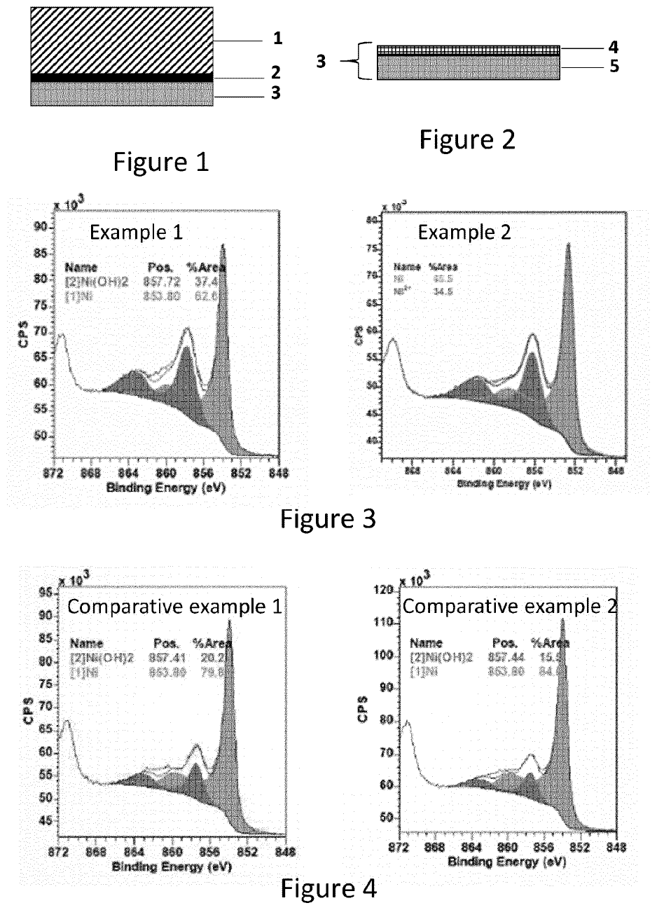

FIG. 1 is a cross-sectional view illustrating a composite copper foil 10 as may be obtained by the present method.

The composite copper foil 10 includes a carrier layer 1, a release layer 2, and an ultra-thin functional layer 3 in this order. The carrier layer 1 and functional layer 3 may also conventionally be referred to as carrier foil and functional foil, respectively. The release layer 2 includes a ternary alloy including nickel, molybdenum and tungsten, and is preferably formed as an amorphous layer. The functional foil 3 is an ultrathin copper foil having a predetermined thickness depending on the use case. As indicated by the arrow in FIG. 1, the ultra-thin copper foil 3 may be peeled off from the carrier foil 1, the separation occurring at the interface with the release layer 2.

Hereinafter, each layer of the composite copper foil according to an embodiment of the present invention will be described.

### Carrier Foil

According to an embodiment of the present invention, the carrier foil 1 is a support layer for supporting the ultrathin functional foil 3. The carrier foil 1 serves as a reinforcing member or support for supporting the functional foil 3 until it is bonded to a substrate.

As is known in the art, the surface roughness of the carrier layer 1 impacts the adhesion strength between the ultra-thin copper layer 3 and a resin substrate. For example, when the adhesion strength is required to be high, the surface roughness of the carrier layer 1 is preferably large. On the other hand, when it is necessary to form a fine circuit, the roughness of the carrier layer 1 is preferably small. In an embodiment of the present invention, a surface roughness Rz (JIS) of the side of the carrier layer on which the release layer 2 and the ultra-thin copper foil 3 are formed is preferably 2.5 μm or less, more preferably of about 2.0 μm. Although a thickness of the carrier foil 1 is not particularly limited, it is normally sufficient to be self-supporting. For example, the carrier foil may have a thickness in a range from 12 μm to 70 μm in consideration of cost, process, and characteristics.

Although a material of the carrier layer 1 is not particularly limited, a copper foil is preferable in consideration of cost, process, and characteristics.

### Release Layer

The release layer 2 is a layer that is designed to allow convenient peeling of the functional foil 3 (i.e. ultra-thin copper foil) from the carrier foil 1. Thanks to the release layer 2, the carrier layer 1 may be easily and neatly detached from the functional foil 3. When the carrier foil 1 and functional foil 3 are detached from one another, the separation occurs essentially at the interface between the release layer 2 and functional foil 3. That is, the release layer 2 is detached from the functional foil 3 together with the carrier foil 1 and hence remains on the carrier foil 1.

The release layer 2 comprises a ternary alloy including nickel, and more preferably the release layer comprises (or consists of) a ternary alloy of nickel, molybdenum and tungsten. In embodiments, the ternary alloy layer of the release layer has a Ni content ranging from 1000 μg/dm² to 3000 μg/dm², a Mo content ranging from 300 μg/dm² to 1600 μg/dm², and a W content of 5 μg/dm² or more. Within the bulk of the release layer, Ni, Mo and W are essentially in metallic form.

It should be however noted that the side of the release layer facing/supporting the functional copper foil comprises oxides forms of the components/elements of the ternary alloy. The peel strength of the surface of the release layer 2 in contact with the ultra-thin copper foil 3 may be controlled by controlling the amount of oxides.

The release layer 2 is formed into an amorphous layer, i.e. the alloy of the release layer is preferably an amorphous alloy.

An amorphous alloy, also called a non-crystallizing alloy, refers to an alloy that has an irregular atomic structure such as a liquid. Since the release layer 2 is amorphous, crystal growth with orientation in a specific direction is hardly achieved, and the release layer 2 includes little grain boundary. In addition, since the release layer 2 is amorphous, and it hardly has a crystal structure even when observed up to the molecular unit, it has higher rigidity and uniform surface as compared to a general metal material. That is, the release layer 2 has a smooth surface. The release layer 2 that is amorphous may be formed by any conventional method such as a vapor deposition method, a sputtering method, and a plating method, but it is preferable to use a plating method. In particular, it is more preferable to use a wet plating method, i.e. electrodeposition.

The thickness of the release layer may vary depending on the producing method thereof, and is not particularly limited but is in the range from 30 to 50 nm. However, the thickness of the release layer 2 is most preferably in a range from 35 to 50 nm irrespective of the method of forming the release layer. In preferred embodiments, the release layer is electroplated onto the carrier foil 1 and the thickness of the release layer may be adjusted (i.e. controlled) by varying the composition of the electrolyte and the electroplating conditions (such as e.g. current density and temperature of the electrolyte).

Moreover, since the release layer 2 is formed into an amorphous alloy layer, an oxide film formed on the release layer 2 also hardly has fine irregularities due to grain boundaries. Thus, even in the case of an oxide film, a smooth and dense surface may be formed. Accordingly, pinhole defects may be significantly reduced.

### Functional Foil

The functional copper foil is an ultrathin layer of copper that is meant to detach from the carrier and to remain on a substrate, in particular to form a copper clad laminate. In other words, the ultra-thin copper layer (functional foil) is peelable (i.e. capable of being separated) from the carrier layer 1.

Advantageously, the functional foil is formed in a two-step process, and therefore includes a first copper layer 4 (or covering layer) and a second copper layer 5, as shown in FIG. 2.

The two layers 4, 5 are formed one on top of another to obtain the functional foil 3 (or ultra-thin copper foil or ultra-thin copper layer) with the desired thickness. Although formed in two steps, the resulting functional foil 3 is a coherent foil that behave as a single layer. As indicated before, the separation from the carrier foil occurs at the interface with the release layer and not within the functional foil 3. That is the two copper layers 4,5 do not separate when the carrier foil is detached. The thickness of the ultra-thin copper layer 3 may vary depending on the producing method thereof, and is not particularly limited but is in the range from 0.5 to 10 μm. However, the thickness of the ultra-thin copper layer 3 is most preferably in a range from 5 μm to 9 μm irrespective of the method of forming an ultra-thin copper layer. The method of forming the ultra-thin copper layer 5 is not particularly limited, but the copper layer is preferably produced by electroplating. The covering layer 4 is typically a very thin layer of copper or copper alloy plated from an alkaline bath. The microstructure of this covering copper layer 4 is very thin compared to the bulk of the functional foil 3 in order to have a more compact and covering layer

In a subsequent step, the exposed surface of the ultra-thin copper foil 3 (i.e. the surface opposed to the surface contacting the release layer) may be subjected to an electrochemical or chemical surface treatment, such as a bond enhancing treatment and/or a passivation treatment (not shown).

### Resin Layer

An embodiment of the present invention provides a copper clad laminate wherein a substrate comprising a resin is laminated onto the ultra-thin copper foil. Herein, the resin of the substrate may be of any kind, as long as the glass transition temperature (Tg) of the resin is lower than the temperature of the lamination process carried out to form the copper clad laminate. In embodiments, the Tg of the resin is lower than 170 °C, preferably lower than 160 °C or lower than 150 °C. The resin of the substrate may comprise an epoxy-based resin, a polyimide-based resin, a maleimide-based resin, a triazine-based resin, a polyphenylene-based resin or a polybutadiene-based resin.

### Fabrication Method

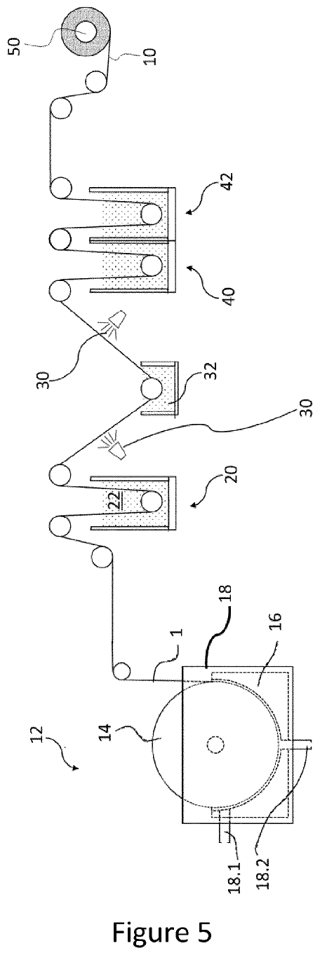

With reference to FIG. 5, a fabrication method will now be described.

As indicated above, the carrier foil may be any appropriate self-supporting layer. Preferably, the carrier foil 1 is an electrodeposited copper foil. Typically, the electrodeposited carrier foil may be manufactured in a continuous manner using an electroforming cell 12 (referred as plating machine in the industry) In the electroforming cell, an electrolyte (an acidic copper bath with additives) is passed through an apparatus comprising a tank 18 with an tank inlet 18.1 and a tank outlet 18.2, a drum-shaped cathode 14 (the surface of which is made of stainless steel or titanium) which is rotating and a stationary anode 16 (a lead or a titanium electrode covered by a precious metal oxide) which is provided opposite the cathode. An electric current is passed through both electrodes to deposit copper on the surface of the cathode with a desired thickness, thus forming an electrodeposited copper foil. The electrodeposited copper foil 1 is then peeled off from the surface of the cathode 14 and may be coiled onto a storage reel or directly passed to a first treatment bath. Such a process of manufacturing an electrodeposited copper foil is well-known and can be used to manufacture a copper carrier foil suitable for the present process.

### Depositing the Release Layer

The releaser layer is formed on one side of the electrodeposited copper carrier foil, typically on the drum side. It is preferable but not invariably necessary that a surface of the carrier layer 1 onto which the release layer is formed is pretreated before deposition of the release layer 2. The pretreatment method is not particularly limited, and methods such as acid cleaning, alkali degreasing, and electrolytic cleaning are generally used.

The release layer is preferably formed by electroplating, directly on the surface of the carrier foil. The carrier foil is therefore guided through a second electroplating cell 20 containing an electrolyte 22 with nickel, molybdenum and tungsten, possibly with desired additives, and the carrier foil is put at cathodic potential.

The electrolyte for the release layer is typically an acidic aqueous solution.

A nickel compound, a molybdenum compound, and a tungsten compound may be used as sources for nickel, molybdenum, and tungsten, respectively. For example, nickel sulfate hydrate may be used as the nickel compound; a molybdenum sodium or a hydrate thereof, e.g., molybdenum dihydrate, may be used as the molybdenum compound; and a tungsten or a hydrate thereof, e.g., tungsten dihydrate, may be used as the tungsten compound. A solvent of the electrolyte is not particularly limited as long as it is a commonly used solvent, but water is generally used.

A concentration of the metals used in the electrolyte bath may be appropriately selected depending on the type of the metal. For example, to form an amorphous alloy layer of Ni, Mo, and W, it is preferable that a concentration of Ni is 5 g/L to 9 g/L, more preferably 7.0 to 9.0 g/L, a concentration of Mo is 5 g/L to 9 g/L, and a concentration of W is 1 to 5 g/L.

A temperature of the electrolyte is generally in a range from 5 °C to 70 °C, and preferably in a range from 10 °C to 50 °C. A current density is generally in a range from 0.2 A/dm² to 10 A/dm², and preferably in a range from 0.5 A/dm² to 5 A/dm². Advantageously, induced co-deposition of the three metals of the ternary alloy occurs due to the tungsten compound, and thus an amorphous layer may be formed.

The pH of the electrolyte may vary depending on the type of metal forming the alloy to be comprised in the release layer. For example, to form a release layer comprises an alloy of nickel, molybdenum and tungsten, it is preferable to adjust the pH of the electrolytic bath to a range from 2.0 to 5.0, or e.g. 2.5 to 4.5. This is because it is advantageous to form an amorphous alloy layer. When the pH of the electrolytic cell is less than 2.0, a crystalline alloy layer may be formed, and when the pH of the electrolytic cell is more than 5.0, only a thin film may be obtained since electroplating and precipitation are hard to be performed at such a pH.

The release layer may be formed in one or more passes, i.e. through a single or multiple electrodeposition steps.

Whatever the fabrication method, the release layer is formed to achieve the desired thickness or specific density (mass per surface unit).

### Washing Step

It will be appreciated that, after being formed (i.e. deposited) onto the carrier foil, the release layer with the desired thickness or specific density is subjected to a washing step. In particular, the washing step is carried out using a washing solution (or rinse water) having a pH within a prescribed range.

The washing solution is typically an aqueous solution. It may have a pH comprised between 2.5 and 4.5, preferably between 2.5 and 4.0, more preferably between 2.5 and 3.5. For ease of implementation, the washing solution may comprise a substantial amount of water, e.g. more than 90, 95 or 99 wt. %. of water with respect to the total weight of the washing solution.

In practice, the washing solution is sprayed with nozzles 30 onto the exposed surface of the release layer (i.e. onto the surface of the release layer opposite to the surface in contact with the carrier foil). The washing solution may be sprayed onto the release layer during 10 to 50 s, in a single step or several times. In some embodiments, the washing step is carried out according to the following sequence: spraying the washing solution onto the release layer, dipping the carrier foil with the release layer thereon into a bath 32 of the washing solution, and spraying the washing solution onto the release layer exiting the bath.

This washing step allows forming oxides at the surface of the release layer, which provide the desired peeling behavior for low temperature lamination processes.

After washing, the carrier foil with the released layer deposited thereon may be wiped, e.g. passed between pressing rollers (such as e.g. nip rollers), before being conveyed to a bath for the electrodeposition of the functional foil.

### Electrodepositing the Functional Foil

As previously indicated, the functional foil is formed in two steps.

A first copper layer (copper or copper alloy) is formed directly on the release layer, i.e. on the washed and dried side of the release layer.

The first copper layer is formed by electroplating in an alkaline copper plating bath 40. The alkaline bath preferably comprises pyrophosphate, cyanate and/or sulfamate ions. The current rate is controlled to form a thin, compact and uniform cover layer. This first/covering copper foil is very thin and designed as strike layer, useful to avoid pinholes and facilitate deposition of copper at higher rates. Next, the second copper layer is electroplated on the first copper layer using a copper acidic bath 42, typically a copper sulfate bath. This second copper layer is grown until the desired thickness of the ultrathin copper foil is achieved. The obtained composite copper foil is finally rolled on a receiving drum 50.

### Examples

Composite copper foils were produced using either a method according to the invention (examples) or a comparative method (comparative examples) not forming part of the invention. The method according to the invention and the comparative method differ from each other by at least one of the washing step of the release layer and the depositing condition of the release layer.

Both for the example and the comparative example, a similar copper foil was used as a carrier foil and first acid cleaned.

Then, both for examples and comparative examples, an alloy release layer was formed on the carrier layer by performing electroplating using an electrolyte including nickel (Ni), molybdenum (Mo), and tungsten (W). Amounts of Ni, Mo and W in the respective baths are presented in Table 1. Deposition of the release layer was performed using an electrolyte having a pH comprised between 2 and 5 and a temperature comprised between 15 and 60 °C, and by applying a current density comprised between 0.8 and 8 A/dm². The release layer of foils according to the examples were washed with a washing solution having a pH comprised between 2.5 and 4.5 in order to oxidize the surface to form oxides. The release layer of foils according to some comparative examples were also washed with a washing solution having a pH comprised between 2.5 and 5.0.

The pH of the respective washing solutions for foils according to the invention, and if applicable for comparative foils, are presented in Table 1.

In practice the washing step is performed by spraying the carrier foil supporting the release layer with the washing solution when it comes out of the electrolyte bath for the release, dipping it in a bath of washing solution and further spraying washing solution thereon, before it enters the next electroplating bath for the ultrathin copper foil.

The plating of the ultrathin copper foil was done in two steps. First, a covering layer is was plated onto the release layer (i.e. on the washed/oxidized surface thereof) using an alkaline plating bath to form a very thin continuous covering layer.

Next, a second copper layer was plated onto the first layer using an acidic copper sulfate bath, with a thickness required to obtain the desired thickness of the ultrathin copper foil.

The main distinctive characteristics of composite copper foils according to the invention and to comparative embodiments are presented in Table 1.

The obtained composite copper foils (both according to the invention and to comparative examples) were then laminated onto a substrate and the peel strength was measured.

Lamination processes and peel strength measurements are generally known in the art and are only briefly presented below.

### Lamination Process

To determine the behaviour of the foils during lamination, they are subjected to lamination at 170 °C: the composite copper foil is laminated at 170 °C on epoxy resin FR4 for 1 hour.

### Peel Strength Measurement

The peel strength (or release strength) between the carrier and the ultra-thin copper foil is measured at 90°. The test is carried out according to IPC-TM-650 Method 2.4.8.5. Peel strength values are presented in Table 1.

As apparent from Table 1, all the composite copper foils according to the invention (examples 1 to 4) present, after lamination at 170 °C for 1 h, a peel strength comprised between 30 and 120 N/m. The inventive composite copper foils are peelable within a convenient peel force, after low temperature lamination. The carrier layer of the composite copper foil produced according to the invention hence still sticks to the ultrathin copper layer after lamination at 170 °C, the peel strength being comprised between 30 and 120 N/m. The copper layer can be further processed (drilled, . . . ) before peeling of the carrier layer.

TABLE 1

| | | | | | Peel strength (N/m) |
|---|---|---|---|---|---|
| | [Ni] | [Mo] | [W] | pH of | after lamination at |
| Sample | (g/L) | (g/L) | (g/L) | washing step | 170 C for 1 h |
| Example 1 | 6.5 | 5.5 | 3.0 | 3.4 | 92 |
| Example 2 | 6.5 | 5.5 | 3.0 | 2.7 | 62 |
| Example 3 | 9.0 | 6.0 | 1.5 | 2.7 | 42 |
| Example 4 | 9.0 | 6.0 | 2.0 | 2.7 | 52 |
| Comparative | 10.0 | 6.0 | 3.0 | No washing | 3 |
| example 1 | | | | | |
| Comparative | 7.5 | 6.0 | 2.5 | No washing | 4 |
| example 2 | | | | | |
| Comparative | 9.5 | 6.30 | 2.1 | 2.7 | 18 |
| example 3 | | | | | |
| Comparative | 9.0 | 6.30 | 0.5 | 2.7 | 28 |
| example 4 | | | | | |
| Comparative | 6.0 | 4.5 | 3.0 | 3.4 | 20 |
| example 5 | | | | | |
| Comparative | 6.0 | 5.0 | 3.0 | 5.0 | 155 |
| example 6 | | | | | |

By contrast, when there is no washing step (comparative examples 1 and 2) the composite copper foil presents—after lamination a 170 °C for 1 h—a peel strength of less than 5 N/m, meaning that the carrier foil is too easily detachable just after the lamination. The carrier foil cannot act as protection during the different subsequent manufacturing steps of the printed circuit board and the ultrathin copper foil cannot be further processed. In other words, the composite foils of the comparative example 1 and 2 are not suitable for low temperature lamination processes.

And when the washing step is performed using a washing solution having a pH of 5.0, i.e. out of the prescribed range, the peel strength becomes too high, meaning that the ultra-thin copper foil becomes unpeelable from the carrier foil.

Moreover, when the release layer is deposited using an acidic electrolyte comprises Ni, Mo or W not in the prescribed ranges (such as more Ni—comparative example 3, less W—comparative example 4, or less Mo—comparative example 5), the peel strength—while being substantially higher than for comparative examples 1 and 2 and being sufficient to ensure cohesion of the composite copper foil during subsequent manufacturing steps thereof, is not as high as for the inventive copper foils, and lower than 30 N/m.

As a further comparison, the inventive composite copper foils was subjected to high temperature lamination (2 h at 220 °C) and came out unpeelable, whereas the composite copper foil of the comparative example 1 exhibited a peel strength of 15 N/m.

As a result, only a method for producing a composite copper foil corresponding to the present invention, i.e. comprising depositing the release layer using an acidic electrolyte comprising Ni, Mo and W at the prescribed concentrations, and comprising a step of washing the release layer prior to the deposition of the ultra-thin copper foil, allows the manufacture of composite copper foils having a high release strength adapted for low temperature lamination.

In order to further characterize the different composite copper foils, X-ray photoelectron spectroscopy (XPS) measurements have been done at the surface of the release layer after peeling of the functional foil. Measurements were performed in the Nickel (Ni) region of binding energy for both composite copper foils according to the invention (FIG. 3—examples 1 and 2) and for composite copper foils according to comparative examples (FIG. 4—comparative examples 1 and 2).

As can be observed, for both the release layer of the example and of the comparative example, nickel is mainly metallic and oxidized nickel is mainly in the state with an oxidation degree of +II. Ni²⁺ is mainly in oxide form or hydroxide form. As displayed on FIG. 3, the amount of Ni(+II) is more important at the surface of the release layer of the examples, i.e. of the samples with the higher release strength, with respect to the comparative example (FIG. 4).

1. A method for producing a composite copper foil comprising a carrier foil, a release layer and an ultra-thin copper foil, the ultra-thin copper foil being peelable from the carrier foil, the method comprising:
providing a carrier foil;
depositing a release layer comprising a ternary alloy of nickel, molybdenum and tungsten on the carrier foil, using an acidic electrolyte comprising nickel, molybdenum and tungsten, the release layer being an amorphous layer;
washing an exposed side of the release layer on the carrier foil with a washing solution having a pH comprised between 2.5 and 4.5;
electroplating an ultra-thin copper foil on the release layer.

2. The method according to claim 1, wherein the pH of the washing solution is comprised between 2.5 and 4.0.

3. The method according to claim 1, wherein the washing solution comprises water and an acid, preferably an inorganic acid.

4. The method according to claim 1, wherein washing the exposed side of the release layer comprises spraying with and/or dipping in the washing solution.

5. The method according to claim 1, wherein washing the exposed side of the release layer is performed for a time period comprised between 10 and 50 s.

6. The method according to claim 1, wherein a washed released layer is left in air for 10 to 40 seconds.

7. The method according to claim 1, wherein the acidic electrolyte comprises nickel at a concentration between 5.0 and 9.0 g/L, molybdenum at a concentration between 5.0 and 9.0 g/L and tungsten at a concentration between 1.0 and 5.0 g/L.

8. The method according to claim 1, wherein electroplating the ultra-thin copper foil comprises:
electroplating directly on the release layer a first copper layer using an alkaline copper electrolyte; and
electroplating a second copper layer on the first copper layer using an acidic copper electrolyte.

9. The method according to claim 8, wherein the alkaline bath comprises pyrophosphate, cyanate and/or sulfamate ions.

10. A composite copper foil comprising a carrier foil, a release layer and an ultra-thin copper foil in this order, wherein the release layer comprises a ternary alloy of nickel, molybdenum and tungsten formed as amorphous layer, and wherein a peel strength of the release layer is comprised between 30 and 120 N/m after lamination at 170 C for 1 h.

11. The composite copper foil as claimed in claim 10, wherein the release layer comprises, at its interface with the ultra-thin copper foil, oxide forms of the ternary alloy comprised in the release layer.

12. The composite copper foil as claimed in claim 10, wherein at the interface with the ultrathin copper foil, the release layer includes oxide forms of nickel, wherein nickel with an oxidation state of +II represents at least 30% by weight, of the total amount of the nickel at the surface.

13. The composite copper foil as claimed in claim 10, wherein the release layer has a thickness between 5 and 50 nm.

14. The composite copper foil as claimed in claim 10, wherein a thickness of the ultra-thin copper foil is comprised between 5.0 and 9.0 μm.

15. The composite copper foil as claimed in claim 10, wherein the composite copper foil is produced using a method as claimed in claim 1.

16. A copper clad laminate comprising a substrate with a resin and a composite copper foil including a carrier foil, a release layer and an ultra-thin copper foil in this order, wherein the release layer comprises a ternary alloy of nickel, molybdenum and tungsten formed as amorphous layer, the ultra-thin copper foil being laminated onto an exposed surface of the substrate,
wherein the resin of the substrate has a Tg lower than 170 °C, and
wherein, after lamination at 170 C for 1 h, a peel strength of the composite copper foil is comprised between 30 and 120 N/m.
